(19) United States
(12) Patent Application Publication
(10) Pub. No.: US 2026/0362603 A1
(43) Pub. Date: Nov. 12, 2026

(54) POWER TOOL INCLUDING WIRE TRAPS ON A PRINTED CIRCUIT BOARD

(71) Applicant: MILWAUKEE ELECTRIC TOOL CORPORATION, Brookfield, WI (US)

(72) Inventors: Amith J. Baskaran, Menomonee Falls, WI (US); Kentez L. Craig, Milwaukee, WI (US); Brian T. Callen, Wauwatosa, WI (US); Daniel J. Tomcheck, Denmark, WI (US); Kirtan A. Jha, Milwaukee, WI (US)

(21) Appl. No.: 19/669,464

(22) Filed: May 6, 2026

Related U.S. Application Data
(60) Provisional application No. 63/804,237, filed on May 12, 2025.

(51) Int. Cl. H05K 1/183; H01R 12/71; H05K 1/02; H05K 7/14

(52) U.S. Cl. CPC H05K 1/183; H01R 12/712; H05K 1/021; H05K 7/14322; H01R 2201/10; H05K 2201/1009

(57) ABSTRACT

A power tool comprising a motor and a printed circuit board (“PCB”) electrically connected to the motor. The PCB further comprises a wire trap assembly positioned on a first side of the PCB, a wire at least partially positioned with respect to the PCB via the wire trap assembly, and a heatsink positioned on a second side of the PCB opposite the first side of the PCB.

### RELATED APPLICATIONS

This application claims the benefit of U.S. Provisional Patent Application No. 63/804,237, filed May 12, 2025, the entire content of which is hereby incorporated by reference.

### FIELD

Embodiments described herein generally relate to printed circuit boards for power tools and, in particular, printed circuit boards included in a power tool having one or more wire traps.

### SUMMARY

Conventional printed circuit boards used in power tools and other electrically driven devices often rely on ad hoc wire routing solutions, such as free‑laid conductors, adhesive retention, or housing‑based clips, to manage electrical wiring proximate the board. These approaches can result in inconsistent wire placement, interference with electronic components, obstruction of thermal management features, and increased susceptibility to damage during assembly, vibration, or impact events. In particular, routing wires across populated board surfaces can limit component density, impede airflow or heat dissipation, and introduce reliability risks when wires migrate or contact sensitive components during use.

Embodiments described herein address these and other challenges by integrating a dedicated wire‑retention structure directly onto the printed circuit board, enabling controlled wire routing and mechanical protection without reducing available board area or compromising thermal performance. By positioning wire‑guiding structures on a first side of the board while positioning heat‑generating components and heatsinking arrangements on an opposite side, the disclosed configurations decouple wire management from thermal management in a manner. The wire trap structures further provide mechanical stand‑off and impact‑protection functions, allowing wires to be guided, retained, and protected relative to the board while maintaining clearance for underlying components and adjacent housings. As a result, the disclosed arrangements improve board reliability, assembly repeatability, and power‑density utilization, while facilitating more compact and robust electronic assemblies.

Embodiments described herein provide a power tool comprising a motor and a printed circuit board (“PCB”) electrically connected to the motor. The PCB further comprises a wire trap assembly positioned on a first side of the PCB, a wire at least partially positioned with respect to the PCB via the wire trap assembly, and a heatsink positioned on a second side of the PCB opposite the first side of the PCB.

In some embodiments, a thermal pad is positioned between the heatsink and the PCB.

In some embodiments, the wire trap assembly includes a plurality of wire trap stems. At least one of the plurality of wire trap stems may extend perpendicularly from the first side of the PCB. In some embodiments, at least one of the plurality of wire trap stems forms a highest point of components positioned on the first side of the PCB. In some embodiments, at least one of the plurality of wire trap stems forms a side of a channel receiving the at least one wire. The power tool may also include a housing, wherein, of components positioned on the first side of the PCB, at least one of the plurality of wire trap stems is positioned closest to a portion of the housing.

In some embodiments, the wire trap assembly includes a base, wherein the base is mounted to the first side of the PCB with at least one of a fastener and an adhesive.

In some embodiments, the PCB is positioned in a handle of the power tool.

In some embodiments, the wire trap assembly includes a base, the base supporting a plurality of wire trap stems. At least a portion of the base may be hollow. In some embodiments, the base includes at least one detent interfacing with a surface of the first side of the PCB.

Embodiments described herein provide a printed circuit board assembly including a PCB including a first side and a second side opposite the first side, a wire trap assembly positioned on the first side of the PCB, a wire at least partially positioned with respect to the PCB via the wire trap assembly, and a heatsink positioned on the second side of the PCB opposite the first side.

In some embodiments, the wire trap assembly includes a wire trap stem that forms a highest point of components positioned on the first side of the PCB.

In some embodiments, at least a portion of the wire trap assembly does not directly contact at least a portion of the first side of the PCB such that one or more electronic components are positioned between the wire trap assembly and the first side of the PCB.

In some embodiments, the printed circuit board assembly further includes a thermal pad positioned between the heatsink and the second side of the PCB.

In some embodiments, the printed circuit board is positioned within a housing that forms a handle of a power tool, and wherein, of components positioned on the first side of the printed circuit board, at least one wire trap stem is positioned closest to a portion of the housing.

In some embodiments, the wire trap assembly includes a plurality of wire trap stems, and wherein at least two of the plurality of wire trap stems define a channel configured to receive the wire.

In some embodiments, the wire trap assembly includes a base, wherein the base includes a detent configured to stand the base off from the first side of the PCB.

In some embodiments, the wire trap assembly includes a wire trap stem that is configured to retain the wire secured relative to the PCB.

Before any embodiments are explained in detail, it is to be understood that the embodiments are not limited in application to the details of the configurations and arrangements of components set forth in the following description or illustrated in the accompanying drawings. The embodiments are capable of being practiced or of being carried out in various ways. Also, it is to be understood that the phraseology and terminology used herein are for the purpose of description and should not be regarded as limiting. The use of “including,” “comprising,” or “having” and variations thereof are meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings.

Unless the context of their usage unambiguously indicates otherwise, the articles “a,” “an,” and “the” should not be interpreted as meaning “one” or “only one.” Rather, these articles should be interpreted as meaning “at least one” or “one or more.” Likewise, when the terms “the” or “said” are used to refer to a noun previously introduced by the indefinite article “a” or “an,” “the” and “said” mean “at least one” or “one or more” unless the usage unambiguously indicates otherwise.

In addition, it should be understood that embodiments may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one embodiment, the electronic-based aspects may be implemented in software (e.g., stored on non-transitory computer-readable medium) executable by one or more processing units, such as a microprocessor and/or application specific integrated circuits (“ASICs”). As such, it should be noted that a plurality of hardware and software based devices, as well as a plurality of different structural components, may be utilized to implement the embodiments. For example, “servers,” “computing devices,” “controllers,” “processors,” etc., described in the specification can include one or more processing units, one or more computer-readable medium modules, one or more input/output interfaces, and various connections (e.g., a system bus) connecting the components.

Relative terminology, such as, for example, “about,” “approximately,” “substantially,” etc., used in connection with a quantity or condition would be understood by those of ordinary skill to be inclusive of the stated value and has the meaning dictated by the context (e.g., the term includes at least the degree of error associated with the measurement accuracy, tolerances [e.g., manufacturing, assembly, use, etc.] associated with the particular value, etc.). Such terminology should also be considered as disclosing the range defined by the absolute values of the two endpoints. For example, the expression “from about 2 to about 4” also discloses the range “from 2 to 4”. The relative terminology may refer to plus or minus a percentage (e.g., 1%, 5%, 10%) of an indicated value.

It should be understood that although certain drawings illustrate hardware and software located within particular devices, these depictions are for illustrative purposes only. Functionality described herein as being performed by one component may be performed by multiple components in a distributed manner. Likewise, functionality performed by multiple components may be consolidated and performed by a single component. In some embodiments, the illustrated components may be combined or divided into separate software, firmware, and/or hardware. For example, instead of being located within and performed by a single electronic processor, logic and processing may be distributed among multiple electronic processors. Regardless of how they are combined or divided, hardware and software components may be located on the same computing device or may be distributed among different computing devices connected by one or more networks or other suitable communication links. Similarly, a component described as performing particular functionality may also perform additional functionality not described herein. For example, a device or structure that is “configured” in a certain way is configured in at least that way but may also be configured in ways that are not explicitly listed.

Accordingly, in the claims, if an apparatus, method, or system is claimed, for example, as including a controller, control unit, electronic processor, computing device, logic element, module, memory module, communication channel or network, or other element configured in a certain manner, for example, to perform multiple functions, the claim or claim element should be interpreted as meaning one or more of such elements where any one of the one or more elements is configured as claimed, for example, to make any one or more of the recited multiple functions, such that the one or more elements, as a set, perform the multiple functions collectively.

Other aspects of the embodiments will become apparent by consideration of the detailed description and accompanying drawings.

### BRIEF DESCRIPTION OF THE DRAWINGS

FIG. 1 illustrates a power tool, according to embodiments described herein.

FIG. 2 illustrates a control system for the power tool of FIG. 1, according to embodiments described herein.

FIG. 3 is a section view of the power tool of FIG. 1 including a printed circuit board (“PCB”) and a wire trap assembly on the PCB, according to embodiments described herein.

FIG. 4 is a bottom view of the power tool of FIG. 1 including the PCB and the wire trap assembly of FIG. 3, according to embodiments described herein.

FIG. 5 illustrates the PCB and the wire trap assembly of FIG. 3, according to embodiments described herein.

FIG. 6 is a perspective view of the wire trap assembly of FIG. 3, according to embodiments described herein.

FIG. 7 is a perspective view of a first side of a PCB including a wire trap assembly, according to other embodiments described herein.

FIG. 8 is a perspective view of a second side of the PCB of FIG. 7, according to embodiments described herein.

FIG. 9 is a side view of a PCB and a wire trap assembly, according to still other embodiments described herein.

### DETAILED DESCRIPTION

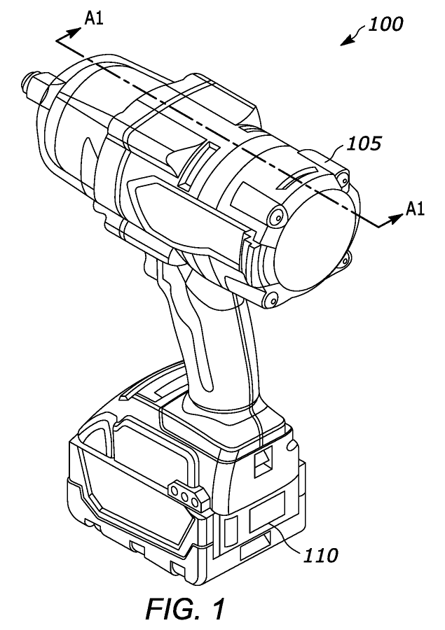

FIG. 1 illustrates a power tool 100. The power tool 100 may be, for example, an impact wrench, a drill, a ratchet, a saw, a hammer drill, an impact driver, a rotary hammer, a grinder, a blower, a trimmer, etc. The power tool 100 includes a housing or a motor housing 105 which houses a motor within the power tool 100. The power tool is configured to receive a power source 110 that provides DC power to the various components of the power tool 100, including the motor. The power source 110 may be a power tool battery pack that is rechargeable and uses, for instance, lithium-ion battery cells. In some embodiments, the power source 110 is an AC power source (e.g., 120V/60Hz) and the power tool 100 receives power from a cord that is coupled to a standard wall outlet.

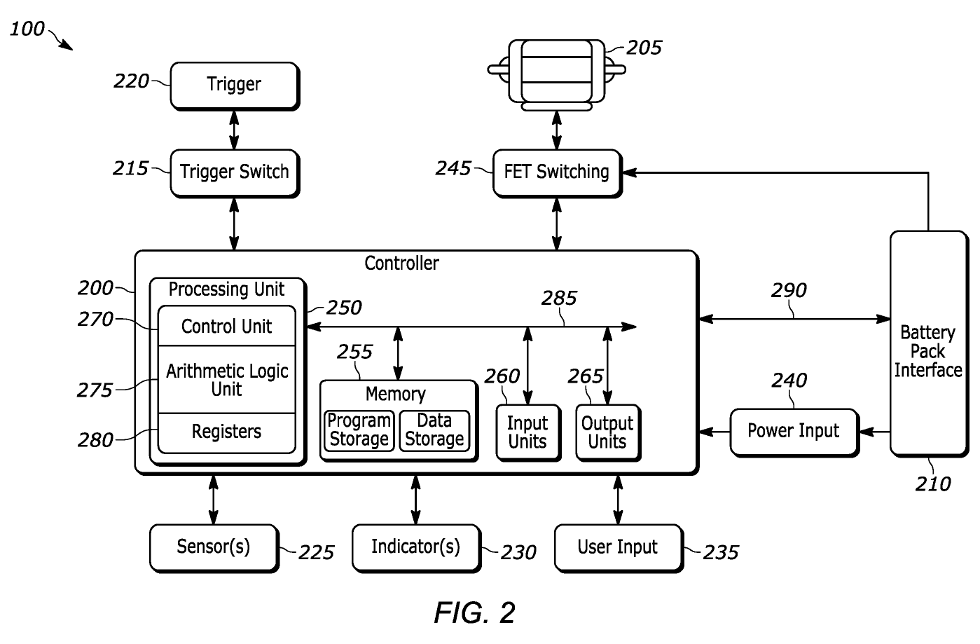

FIG. 2 illustrates a control system for the power tool 100. The control system includes a controller 200. The controller 200 is electrically and/or communicatively connected to a variety of modules or components of the power tool 100. For example, the illustrated controller 200 is electrically connected to a motor 205, a battery pack interface 210, a trigger switch 215 (connected to a trigger 220), one or more sensors or sensing circuits 225, one or more indicators 230, a user input module 235, a power input module 240, and a FET switching module 245 (e.g., including a plurality of switching FETs). The controller 200 includes combinations of hardware and software that are operable to, among other things, control the operation of the power tool 100, monitor the operation of the power tool 100, activate the one or more indicators 230 (e.g., an LED), etc.

The controller 200 includes a plurality of electrical and electronic components that provide power, operational control, and protection to the components and modules within the controller 200 and/or the power tool 100. For example, the controller 200 includes, among other things, a processing unit 250 (e.g., a microprocessor, a microcontroller, an electronic processor, an electronic controller, or another suitable programmable device), a memory 255, input units 260, and output units 265. The processing unit 250 includes, among other things, a control unit 270, an ALU 275, and a plurality of registers 280 (shown as a group of registers in FIG. 2) and is implemented using a known computer architecture (e.g., a modified Harvard architecture, a von Neumann architecture, etc.). The processing unit 250, the memory 255, the input units 260, and the output units 265, as well as the various modules or circuits connected to the controller 200, are connected by one or more control and/or data buses (e.g., common bus 285). The control and/or data buses are shown generally in FIG. 2 for illustrative purposes.

The memory 255 is a non-transitory computer readable medium and includes, for example, a program storage area and a data storage area. The program storage area and the data storage area can include combinations of different types of memory, such as a ROM, a RAM (e.g., DRAM, SDRAM, etc.), EEPROM, flash memory, a hard disk, an SD card, or other suitable magnetic, optical, physical, or electronic memory devices. The processing unit 250 is connected to the memory 255 and executes software instructions that are capable of being stored in a RAM of the memory 255 (e.g., during execution), a ROM of the memory 255 (e.g., on a generally permanent basis), or another non-transitory computer readable medium such as another memory or a disc. Software included in the implementation of the power tool 100 can be stored in the memory 255 of the controller 200. The software includes, for example, firmware, one or more applications, program data, filters, rules, one or more program modules, and other executable instructions. The controller 200 is configured to retrieve from the memory 255 and execute, among other things, instructions related to the control processes and methods described herein. In other constructions, the controller 200 includes additional, fewer, or different components.

The battery pack interface 210 includes a combination of mechanical components (e.g., rails, grooves, latches, etc.) and electronic components (e.g., one or more terminals) configured to and operable for interfacing (e.g., mechanically, electrically, and communicatively connecting) the power tool 100 with a battery pack. For example, power provided by the battery pack 110 to the power tool 100 is provided through the battery pack interface 210 to the power input module 240. The power input module 240 includes combinations of active and passive components to regulate or control the power received from the battery pack 110 prior to power being provided to the controller 200. The battery pack interface 210 also supplies power to the FET switching module 245 to be switched by the switching FETs to selectively provide power to the motor 205. The battery pack interface 210 also includes, for example, a communication line 290 for providing a communication line or link between the controller 200 and the battery pack 110.

The indicators 230 include, for example, one or more light-emitting diodes (“LEDs”). The indicators 230 can be configured to display conditions of, or information associated with, the power tool 100. For example, the indicators 230 are configured to indicate measured electronic characteristics of the power tool 100, the status of the device, etc. The user input module 235 is operably coupled to the controller 200 to, for example, select a forward mode of operation or a reverse mode of operation, a torque and/or speed setting for the power tool 100 (e.g., using torque and/or speed switches), etc. In some embodiments, the user input module 235 includes a combination of digital and analog input or output devices required to achieve a desired level of control for the power tool 100, such as one or more knobs, one or more dials, one or more switches, one or more buttons, etc.

The sensors 225 include one or more current sensors, one or more speed sensors, one or more Hall-effect sensors, one or more temperature sensors, etc. The controller 200 calculates or includes, within memory 255, predetermined operational threshold values and limits for operation of the power tool 100. For example, when a potential thermal failure (e.g., of a FET, the motor 205, etc.) is detected or predicted by the controller 200, power to the motor 205 can be limited or interrupted until the potential for thermal failure is reduced.

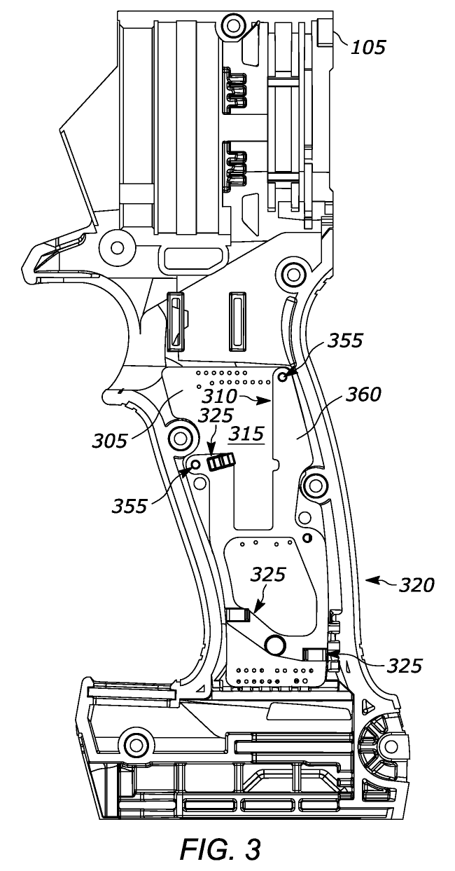

FIG. 3 is a section view of the power tool 100 of FIG. 1 along an axis A1 (which may be defined along a seam of a clam-shell design housing) illustrating the position of a printed circuit board (“PCB”) 305 and a wire trap assembly 310 mounted on a first side 315 of the PCB 305 included in the power tool 100. Some internal components (e.g., motor, wiring, electronic components, etc.) of the tool 100 and the PCB 305 are removed in FIG. 3 to highlight the position of the PCB 305 within the power tool 100 and the position of the wire trap assembly 310 on the PCB 305. As illustrated in FIG. 3, the PCB 305 may be positioned in a portion of the housing 105 forming a handle 320 of the power tool 100. However, it should be understood that the PCB 305 may be positioned in various locations within a housing of the power tool 100. In some embodiments, the housing 105 includes a clam-shell design and the PCB 305 is positioned in one side of the clam-shell design such that the PCB 305 (or at least a portion thereof) does not cross a seam of the clam-shell housing into another side of the clam-shell housing, but the wire trap assembly 310 (or at least a portion thereof) crosses the seam. In other embodiments, the PCB 305 is positioned such that the PCB 305 and the wire trap assembly 310 do not cross the seam and are completely housed in one side of the clam-shell housing. In some embodiments, some components of the PCB 305 are positioned in one side of the clam-shell housing and other components of the PCB 305, or components attached to the PCB 305 (e.g., a heatsink), are positioned in the other side of the clam-shell housing. In some embodiments, the PCB 305 includes the controller 200 or components thereof with respect to the control system illustrated in FIG. 2. For example, the PCB 305 may be electrically connected to the power source 110 and the motor 205.

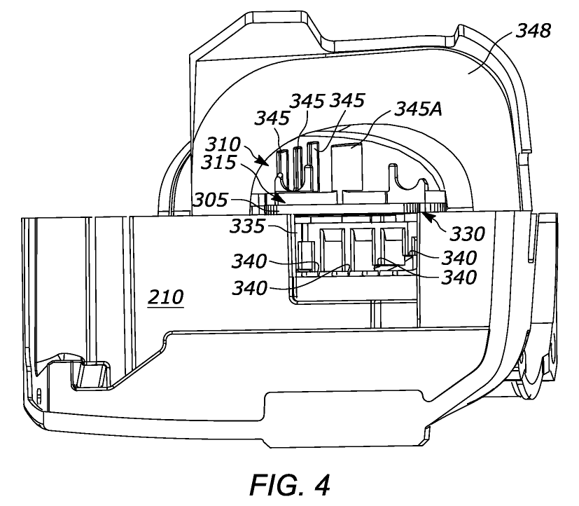

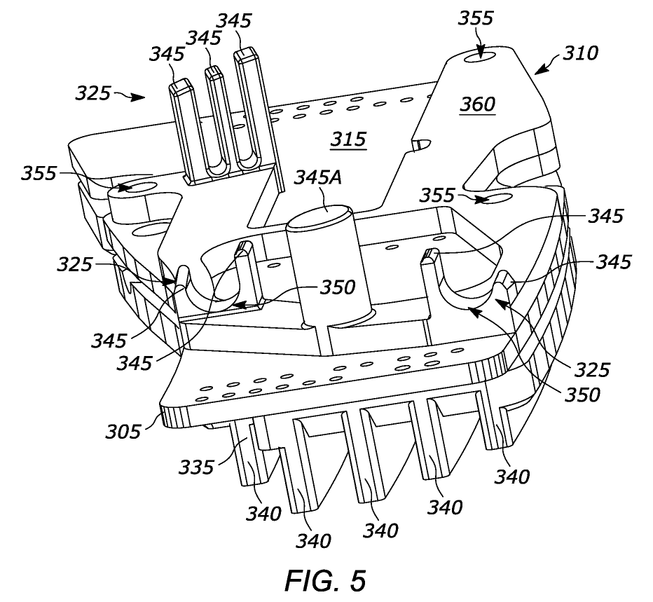

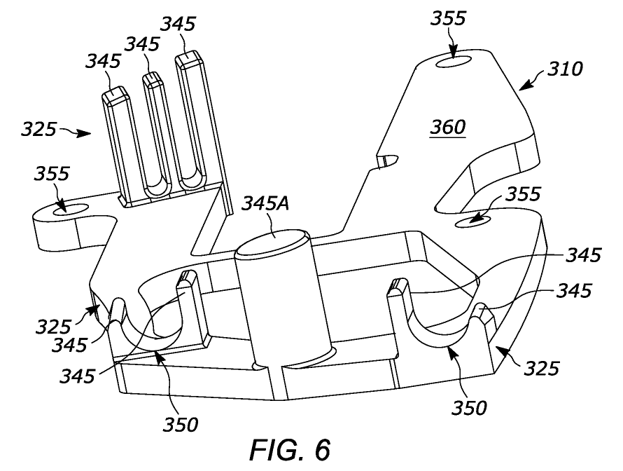

The PCB 305 includes a top surface (i.e., the first side 315) and a bottom surface (i.e., a second side 330, see FIG. 4), wherein the top surface is opposite the bottom surface. As illustrated in FIG. 3, the wire trap assembly 310 is at least partially positioned on the first side 315 of the PCB 305. The wire trap assembly 310 includes one or more wire traps 325. As illustrated in FIGS. 5-6, each wire trap 325 includes at least one wire trap stem 345, which extends away from the first side 315 of the PCB 305. In some embodiments, a wire trap stem 345 extends at an angle relative to the first side 315 of the PCB 305. For example, a wire trap stem 345 may extend approximately perpendicular from the first side 315. However, in other embodiments, a wire trap stem 345 may extend from the first side 315 at other angles, and, in some embodiments, the wire trap assembly 310 may include multiple wire trap stems 345 wherein at least two wire trap stems 345 extend from the first side 315 at different angles. In some embodiments, the top of a wire trap stem 345 is flat, angled, or rounded. In some embodiments, at least one wire trap stem 345 forms a highest point of components (e.g., electrical and/or mechanical components) positioned on the first side 315 of the PCB 305. In other words and as illustrated in FIG. 4, in some embodiments, of the components positioned on the first side 315 of the PCB 305, at least one wire trap stem 345 is positioned closest to a portion of a housing 348 (e.g., a portion of the housing 105) positioned around the PCB 305 (e.g., an opposite side of a clam-shell housing design as described with respect to FIG. 3). Accordingly, in this configuration, one or more of the wire trap stems 345 offer protection for the PCB 305 (and components positioned thereon) when the power tool 100 is dropped, the housing 348 surrounding the PCB 305 is deformed, or another condition that might damage the PCB 305 occurs. Similarly, in some embodiments, one or more of the wire trap stems 345 interface (e.g., contact or engage with a detect, recess, or the like) with the housing 348 (e.g., a portion of the housing 105) to secure the PCB 305.

As illustrated in FIGS. 5-6, a wire trap stem 345 may form a side of a channel 350 shaped to receive at least one wire (e.g., electrical wiring). Accordingly, the wire trap assembly 310 can be used to guide at least one wire around components mounted on the first side 315 of the PCB 305 and/or to be positioned with respect to other components of the power tool 100 not mounted on the PCB 305. The channel 350 may help electrically and/or thermally isolate a wire from an electronic component mounted to the first side 315 of the PCB 305, securely position a wire with respect to the PCB 305, keep a wire from covering or otherwise blocking access to other components of the PCB 305 and/or the power tool 100, or a combination thereof. Accordingly, the channel 350 and the wire trap stems 345 may provide wire organization of the PCB 305. As illustrated in FIGS. 5-6, two or more wire trap stems 345 may be used to form the channel 350 and the size, height, shape, or a combination thereof may be the same or vary between the stems 345. However, in some embodiments, a single stem 345 may be used to guide or secure at least one wire. Also, in some embodiments, the wire trap assembly 310 also includes one or more stems for support purposes. For example, as illustrated in FIGS. 4, 5, and 6, the wire trap assembly 310 may include one or more stems 345A that, while not positioned to guide or position a wire or form a channel for receiving a wire, the stem 345A may retain other components away from the PCB 305 or interface with other components of the power tool 100 to stabilize or secure the PCB 305 within a housing of the power tool 100 (e.g., the housing 348 or other portion of the housing 105).

In configurations where the wire trap assembly 310 includes multiple stems 345, multiple channels 350, or both, stems 345 and/or channels 350 may be physically supported and connected via a base 360 of the wire trap assembly 310. The stems 345, channels, and/or base 360 may be constructed from a nylon material. It should be understood that, in some embodiments, the wire trap assembly 310 may include multiple sections separately mounted on the PCB 305 that may or may not be connected via a common base (e.g., the base 360). The base 360 is used to mount the wire trap assembly 310 to the first side 315 of the PCB 305 and may be integrally formed with the channel 350 as described above. As illustrated in FIG. 5, the base 360 may include one or more through holes 355. The through holes 355 are configured to receive a fastener (e.g., a screw, nail, etc.) for mounting the base 360 on the first side 315 of the PCB 305. In addition, or as an alternative to using a fastener, in some embodiments, the base 360 is mounted to the PCB using an adhesive. Also, in some embodiments, the base 360 may not include the one or more through holes 355 but one or more clips or other types of mechanical fasteners may be used to mount the base 360 onto the first side 315 of the PCB 305.

It should also be understood that, in some embodiments, the base 360, which supports one or more wire trap stems 345, does not directly contact the first side 315 of the PCB 305 except near or at the through holes 355. Such a configuration improves power density by having passive components positioned underneath the wire trap base 360. For example, in some embodiments, at least a portion of the wire trap base 360 is hollow and/or includes one or more detents or similar mechanisms that stand the base 360 off from the surface of the PCB 305.

FIG. 4 is a bottom view of the power tool 100 with the battery pack 110 removed from the battery pack interface 210 and a portion of the housing 105 removed to illustrate a position of the PCB 305 and the wire trap assembly 310 according to some embodiments. As illustrated in FIG. 4, the second side 330 of the PCB 305 is opposite the first side 315 of the PCB 305 (i.e., in parallel planes), and a heatsink 335 is positioned on the second side 330 of the PCB 305. The heatsink 335 dissipates heat generated by the PCB 305 and electronic components mounted on the PCB 305. The heatsink 335 may include a plurality of fins 340. In some embodiments, the heatsink 335 is the same size and/or shape as the second side 330 of the PCB 305; however, the heatsink 335 may also have other sizes and shapes. Also, in some embodiments, the second side 330 of the PCB 305 includes multiple heatsinks and/or other components (e.g., electrical/mechanical). In some embodiments, the electrical components mounted on the PCB 305 include a kelvin resistor. The kelvin resistor measures a current of a motor of the power tool 100. In some embodiments, the heatsink 335 at least partially covers an electronic component mounted on the second side 330 of the PCB 305. In some embodiments, the electronic component that is at least partially covered by the heatsink 335 is a power switch. In addition, in some embodiments, the second side 330 includes one or more wire trap assemblies similar to the assembly 310 described with respect to the first side 315. However, in other embodiments, the wires and associated wire trap assembly 310 may be contained to the first side 315 of the PCB 305 (i.e., a side opposite the side including one or more heatsinks and/or other components) for ease of installation and/or wire organization.

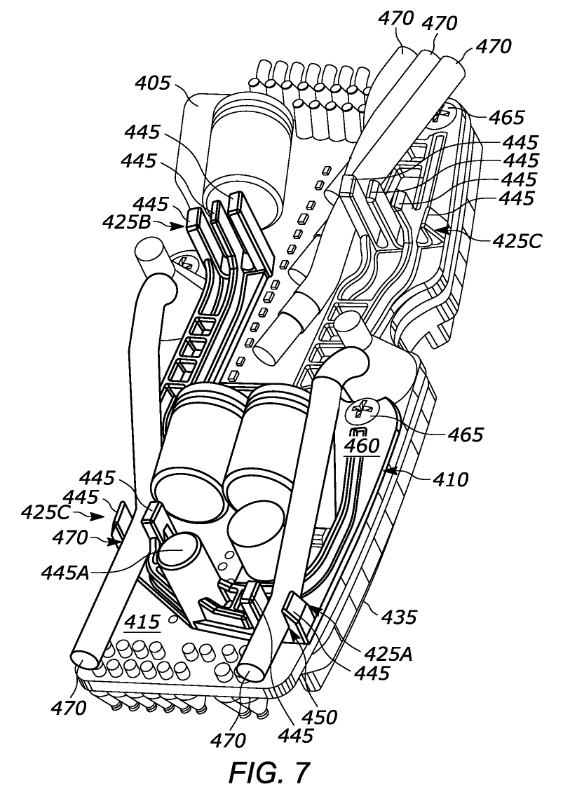

It should be understood that the wire trap assembly 310 can have various shapes, sizes, and configurations of stems, channels, and bases. For example, FIG. 7 illustrates a PCB 405 with a wire trap assembly 410 according to some embodiments. Similar to the wire trap assembly 310, the wire trap assembly 410 includes a plurality of wire trap stems 445 (including, for example, a stem 445A used for support), a plurality of channels 450, and a base 460. Accordingly, as described above with respect to the wire trap assembly 310, the wire trap stems 445 and/or channels 450 form a number of wire traps 425, including, for example, a wire trap 425A, 425B, and 425C configured to restrain and guide one or more wires 470. In some embodiments, the wires 470 that interface with the wire traps 425 connect the battery pack interface 210 of the power tool 100 and the motor of the power tool 100. The wire trap assembly 410 is mounted to a first side 415 of the PCB 405 via one or more fasteners 465 positioned in one or more through holes. However, as noted above with respect to the wire trap assembly 410, the base 460 may be mounted using one or more types of mechanical fasteners and/or via an adhesive.

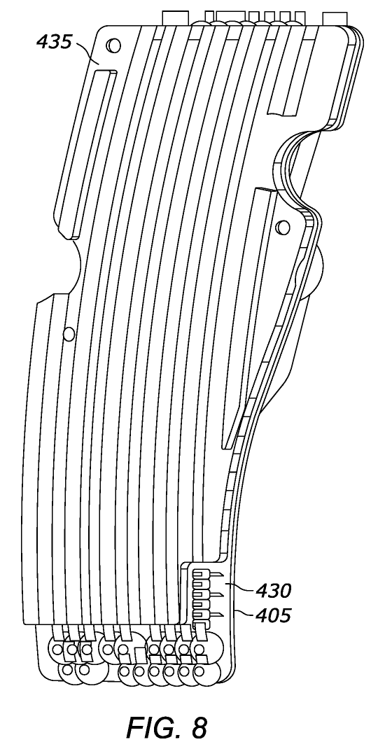

As illustrated in FIG. 7, the PCB 405 includes one or more electronic components mounted on the first side 415 of the PCB 405, wherein the wire traps 425 may be used to route wires 470 around such components or otherwise retain the wires 470 secured to the PCB 405. The first side 415 may include a conductive layer that provides an electrical connection between the PCB 405 and the electronic components and/or metal traces that electrically connect electronic components of the PCB 405. As illustrated in FIG. 8, a heatsink 435 is positioned on a second side 430 of the PCB 405 opposite the first side 415. As illustrated in FIG. 8, the heatsink 435 may be sized and shaped to generally align with the size and shape of the PCB 405. However, other sizes, shapes, and numbers of heatsinks may be positioned on the second side 430 of the PCB 405 in various embodiments. In some embodiments, the electrical components mounted on the PCB 405 include a kelvin resistor. The kelvin resistor measures a current of a motor of the power tool 100. In some embodiments, the heatsink 435 at least partially covers an electronic component mounted on the second side 430 of the PCB 405. In some embodiments, the electronic component that is at least partially covered by the heatsink 435 is a power switch.

In some implementations, heat-producing electronic components associated with the PCB 405, except for one or more capacitors, are mounted on the second side 430 so that the components directly touch the heatsink 435. These components may include one or more MOSFETs, current sense resistors, or a combination thereof. In this implementation, the wires and capacitors are mounted on the first side to, among other things, not block airflow over the heatsink 435.

As illustrated in FIG. 7, the wire trap assembly 410 can take various shapes and include various numbers of stems and/or channels to achieve desired wire routing and guidance. For example, as compared to the wire trap assembly 310 illustrated in FIG. 6, the wire trap assembly 410 includes an additional set of stems 445 (see stems included in wire trap 425C in FIG. 7) to guide one or more wires 470 into the middle of the first side 415 of the PCB 405. This additional set of stems 445 also illustrates how stems can be used to guide one or more wires without requiring a corresponding channel 450. In this configuration, multiple stems 445 may be used for support purposes as described above, even if the multiple stems are not used to form channels for receiving one or more wires.

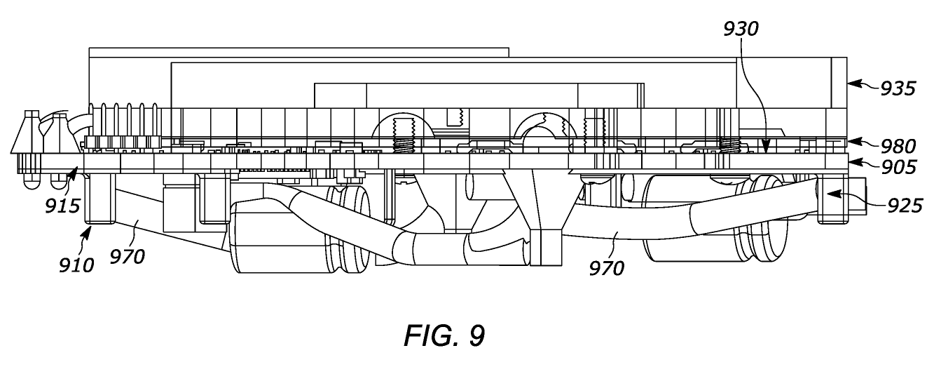

It should also be understood that the wire trap assemblies 310, 410 described herein may be used with various PCBs and PCB assemblies or components. For example, FIG. 9 illustrates a PCB 905 with a wire trap assembly 910 including a plurality of wire traps 925 configured to guide or place one or more wires 970, according to some embodiments. In some embodiments, the wires 970 that interface with the wire traps 925 connect the battery pack interface 210 of the power tool 100 and the motor of the power tool 100. The PCB 905 has a first side 915 and a second side 930. The wire traps 925 and a plurality of electronic/electrical components (e.g., one or more capacitors) are mounted to the first side 915 of the PCB 905, and a heatsink 935 is mounted to the second side 930 of the PCB 905. The first side 915 may include a conductive layer that provides an electrical connection between the PCB 905 and the electronic components and/or metal traces that electrically connect electronic components of the PCB 905. In some embodiments, the PCB 905 includes a kelvin resistor (e.g., mounted on the second side 930). The kelvin resistor measures a current of a motor of the power tool 100. In some embodiments, the heatsink 935 at least partially covers an electronic component mounted on the second side 930 of the PCB 905. In some embodiments, the electronic component that is at least partially covered by the heatsink 935 is a power switch. In the embodiment of FIG. 9, a thermal pad 980 is positioned between the heatsink 935 and the second side 930 of the PCB 905. The thermal pad 980 improves heat transfer between the PCB 905 and the heatsink 935. In some embodiments, the size and shape (e.g., the two-dimensional area) of the thermal pad 980 matches the size and shape of the heatsink 435. The thermal pad may be constructed from a fiberglass-reinforced polymer with the base material being silicone. However, other constructions, sizes, and shapes are possible based on the thermal management needs, the size and shape of the PCB, the type and number of electronic components mounted on the PCB, or a combination thereof.

It should be understood that the different wire trap assembly configurations described herein, and the different PCB configurations described herein, may be used together in various combinations.

Thus, embodiments described herein provide, among other things, wire traps for a PCB. Various features and advantages are set forth in the following claims.

What is claimed is:

1. A power tool comprising:
a motor; and
a printed circuit board (“PCB”) electrically connected to the motor, the PCB further comprising:
a wire trap assembly positioned on a first side of the PCB;
a wire at least partially positioned with respect to the PCB via the wire trap assembly; and
a heatsink positioned on a second side of the PCB opposite the first side of the PCB.

2. The power tool of claim 1, wherein a thermal pad is positioned between the heatsink and the PCB.

3. The power tool of claim 1, wherein the wire trap assembly includes a plurality of wire trap stems.

4. The power tool of claim 3, wherein at least one of the plurality of wire trap stems extends perpendicularly from the first side of the PCB.

5. The power tool of claim 3, wherein at least one of the plurality of wire trap stems forms a highest point of components positioned on the first side of the PCB.

6. The power tool of claim 3, wherein at least one of the plurality of wire trap stems forms a side of a channel receiving the at least one wire.

7. The power tool of claim 3, further comprising a housing, wherein, of components positioned on the first side of the PCB, at least one of the plurality of wire trap stems is positioned closest to a portion of the housing.

8. The power tool of claim 1, wherein the wire trap assembly includes a base, wherein the base is mounted to the first side of the PCB with at least one of a fastener and an adhesive.

9. The power tool of claim 1, wherein the PCB is positioned in a handle of the power tool.

10. The power tool of claim 1, wherein the wire trap assembly includes a base, the base supporting a plurality of wire trap stems.

11. The power tool of claim 10, wherein at least a portion of the base is hollow.

12. The power tool of claim 10, wherein the base includes at least one detent interfacing with a surface of the first side of the PCB.

13. A printed circuit board assembly comprising:
a PCB including a first side and a second side opposite the first side;
a wire trap assembly positioned on the first side of the PCB;
a wire at least partially positioned with respect to the PCB via the wire trap assembly; and
a heatsink positioned on the second side of the PCB opposite the first side.

14. The printed circuit board assembly of claim 13, wherein the wire trap assembly includes a wire trap stem that forms a highest point of components positioned on the first side of the PCB.

15. The printed circuit board assembly of claim 13, wherein at least a portion of the wire trap assembly does not directly contact at least a portion of the first side of the PCB such that one or more electronic components are positioned between the wire trap assembly and the first side of the PCB.

16. The printed circuit board assembly of claim 13, further comprising a thermal pad positioned between the heatsink and the second side of the PCB.

17. The printed circuit board assembly of claim 13, wherein the printed circuit board is positioned within a housing that forms a handle of a power tool, and wherein, of components positioned on the first side of the printed circuit board, at least one wire trap stem is positioned closest to a portion of the housing.

18. The printed circuit board assembly of claim 13, wherein the wire trap assembly includes a plurality of wire trap stems, and wherein at least two of the plurality of wire trap stems define a channel configured to receive the wire.

19. The printed circuit board assembly of claim 13, wherein the wire trap assembly includes a base, wherein the base includes a detent configured to stand the base off from the first side of the PCB.

20. The printed circuit board assembly of claim 13, wherein the wire trap assembly includes a wire trap stem configured to retain the wire secured relative to the PCB.
